(19) United States
(12) Patent Application Publication
(10) Pub. No.: US 2006/0216544 A1
(43) Pub. Date: Sep. 28, 2006

(54) Organic electroluminescent device

(75) Inventors: Kazuki Yamazaki, Kanagawa (JP); Masayuki Mishima, Kanagawa (JP)

Correspondence Address: BIRCH STEWART KOLASCH & BIRCH, PO BOX 747, FALLS CHURCH, VA, 22040-0747, US

(73) Assignee: FUJI PHOTO FILM CO. LTD

(21) Appl. No.: 11/318,400

(22) Filed: Dec. 27, 2005

(30) Foreign Application Priority Data
Mar. 23, 2005 (JP) 2005-84942

(51) Int. Cl. H01L 51/54; H05B 33/12

(52) U.S. Cl. 428/690; 428/917; 313/504; 313/506

(57) ABSTRACT

The invention provides an organic electroluminescent device having at least two luminescent layers provided between a pair of electrodes. Each of the luminescent layers contains a light-emitting material having a structure different from a structure of a light-emitting material contained in other luminescent layers. At least one of the light-emitting materials is a phosphorescence light-emitting material. Each of the luminescent layers is adjacent to another luminescent layer via a buffer layer. Further, the buffer layer includes an organic compound having an energy difference (Eg) between the highest occupied orbit and the lowest non-occupied orbit of 4.0 eV or more. It is preferable that the lowest excited triplet energy level (Ti) of the organic compound is 2.7 eV or more.

### CROSS-REFERENCE TO RELATED APPLICATION

This application claims priority under 35 USC 119 from Japanese Patent Application No. 2005-84942, the disclosure of which is incorporated by reference herein.

### BACKGROUND OF THE INVENTION

1. Field of the Invention

The present invention relates to an organic electroluminescent device that emits light by converting electric energy to light.

2. Description of the Related Art

Various kinds of display devices are being studied and developed actively these days. In particular, an organic electroluminescent device (hereinafter, optionally referred to also as an “organic EL device,” an “electroluminescent device,” or a “device”) attracts attention as a promising display device capable of obtaining a high luminosity light emission with a low voltage. In general, an organic EL device includes counter electrodes with a luminescent layer or a plurality of organic layers including a luminescent layer interposed therebetween so that an electron injected from a cathode and a hole injected from an anode are re-bonded in the luminescent layer so as to utilize the light emission from the produced exciton, or utilize the light emission from the exciton of the another molecule produced by the energy transfer from the above-mentioned exciton.

Since the organic EL device is a surface light source having spontaneous light emission, utilization thereof as a white light source, for example, is conceivable. As defined in the Commission Internationale d'Eclairage (CIE), the ideal white light source has the coordinates of (0.33, 0.33). A white light emission can be obtained with a light emission of light-emitting materials of three colors including blue, green and red, or light-emitting materials of two colors in a complementary color relationship. In this case, when an energy transfer between the light-emitting materials (blue, green, red) is generated in the white light electroluminescent device, a desired chromaticity cannot be obtained. Thus, development of an organic EL device having a high efficiency, a low voltage, a high luminosity and a high chromaticity is called for.

As a means for realizing a high efficiency of the device, use of a phosphorescent light-emitting material in the luminescent layer is available. Several of the current blue (light-emitting) phosphorescent materials have a low light-emitting intensity. For example, in the case where a blue fluorescence material having a low light-emitting intensity is used, in order to obtain a desired chromaticity, adjustment is needed for lowering the phosphorescence light-emitting intensity for green and red colors, and as a result, the light-emitting efficiency of the device is lowered. Thus, a technique for efficiently emitting a light beam from a light-emitting material having a low light-emitting intensity (preferably a phosphorescent light-emitting material) is called for.

As a technique using a plurality of light-emitting materials, an electroluminescent device including two or more kinds of light-emitting materials that are different from each other in a luminescent layer, wherein at least one of the light-emitting materials is an orthometal complex, is disclosed (Japanese Patent Application Laid-Open (JP-A) No. 2001-319780). Moreover, an organic electroluminescent device including a plurality of light-emitting dopants in a luminescent layer, wherein at least one dopant is a phosphorescent light-emitting substance, is disclosed (U. S. Patent Application Publication No. 2002/0197511).

Improvement of a light-emitting efficiency by using a phosphorescent light-emitting material in each of the blue, green and red luminescent layers and trapping an exciton in a luminescent layer by partitioning the luminescent layer with an exciton inhibiting layer is disclosed (see JP-A No. 2004-522276).

An electroluminescent device, wherein a luminescent layer includes a hole transporting luminescent layer and an electron transporting luminescent layer, and the hole transporting luminescent layer includes a tri(o-terphenyl-4-yl) amine, is disclosed (JP-A No. 2001-196183).

### SUMMARY OF THE INVENTION

In the light of the above described circumstances, the present invention provides an organic electroluminescent device having a high efficiency and a high luminosity. In particular, the present invention provides an organic electroluminescent device having a high efficiency, a high luminosity and an excellent chromaticity that is suitable for a white light emission device.

Namely, the present invention provides an organic electroluminescent device comprising at least two luminescent layers provided between a pair of electrodes, wherein: each of the luminescent layers contains a light-emitting material having a structure different from a structure of a light-emitting material contained in other luminescent layers; at least one of the light-emitting materials is a phosphorescence light-emitting material; each of the luminescent layers is adjacent to another luminescent layer via at least a buffer layer; and the buffer layer includes an organic compound having an energy difference (Eg) between the highest occupied orbit and the lowest non-occupied orbit of 4.0 eV or more.

In one aspect of the present invention, the lowest excited triplet energy level (Ti) of the organic compound is 2.7 eV or more.

In another aspect of the present invention, the buffer layer contains a hole transporting material or an electron transporting material.

In another aspect of the present invention, a film thickness of the buffer layer is in a range of 0.5 to 10 m.

In another aspect of the present invention, a content of the hole transporting material or the electron transporting material in the buffer layer is in a range of 1 to 95% by mass relative to the a total mass of the buffer layer.

In another aspect of the present invention, the organic compound is a compound represented by the following Formula (1) or (3).
L-(Ar)ₘ Formula (1)

In Formula (1), Ar is a group represented by the following Formula (2). L is a benzene skeleton having a valence of 3 or more. m is an integer of 3 or more.

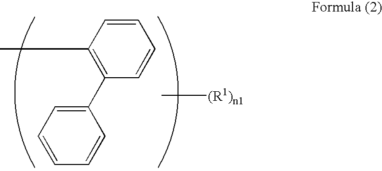

In Formula (2), R¹ is a substituent. In the case where R¹ is present in a plurality, they may either be the same or different from each other. n1 is an integer from 0 to 9.

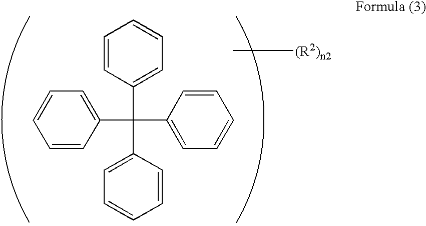

In Formula (3), R² is a substituent. In the case where R²is present in a plurality, they may either be the same or different from each other. n2 is an integer from 0 to 20.

In still another aspect of the present invention, the organic electroluminescent device is characterized by emitting white light.

### DETAILED DESCRIPTION OF THE INVENTION

Hereinafter, the electroluminescent device of the invention will be described in detail.

The organic electroluminescent device of the present invention includes at least two luminescent layers between a pair of electrodes (an anode and a cathode).

Electrodes (an anode and an cathode) and a supporting substrate for forming the electrodes, and an organic compound layer to be used for the present invention is not particularly limited and they can be selected appropriately from conventionally-known products. Considering the characteristics of the electroluminescent device, at least one of the anode and the cathode is preferably transparent.

In the present invention, in addition to at least two luminescent layers, another organic compound layer may be provided. It is a characteristics of the device of the invention that each of the luminescent layers is adjacent to another luminescent layer via at least a buffer layer that includes an organic compound having 4.0 eV or more Eg.

Examples of the layer(s) (organic compound layer(s)) provided between the pair of electrodes include a combination of a luminescent layer and a buffer layer and a stacked structure further having another organic compound layer in addition to the combination. In the case where the organic compound layer has the stacked structure, preferable examples of the embodiment thereof include a stacked structure having a hole-transporting layer, a luminescent layer and an electron-transporting layer which are sequentially stacked from the anode side. Further, a charge blocking layer or the like may be provided between the hole transporting layer and the luminescent layer, or between the luminescent layer and the electron transporting layer. A hole-injecting layer may be provided between the cathode and the electron-transporting layer. An electron-injecting layer may be provided between the cathode and the electron-transporting layer.

Hereinafter, the organic compound layer of the present invention will be explained in detail.

Luminescent Layer

A luminescent layer (organic luminescent layer) is a layer having a light-emitting function by receiving a hole from an anode, a hole injecting layer, or a hole transporting layer, receiving an electron from a cathode, an electron injecting layer, or an electron transporting layer when an electric field is applied thereto, and providing an area for re-combination of the hole and the electron.

The luminescent layer in the present invention may be made of either only a light-emitting material or a layer of a mixture of a host material and a light-emitting material. The host material may either be of one kind or of two or more kinds. Examples thereof include a configuration in which an electron transporting host material and a hole transporting host material are mixed. Further, the luminescent layer may further include a material which has neither a charge transporting property nor a light-emitting property.

According to the present invention, each of the luminescent layers to be provided with at least two layers contains a light-emitting material having a structure different from a structure(s) of a light-emitting material(s) contained in other luminescent layer(s), and at least one of the light-emitting materials is a phosphorescent light-emitting material.

According to the present invention, an electroluminescent device capable of emitting a light beam of intended color can be obtained by using at least two kinds of the light-emitting materials, each of which has a structure different from each other, and at least one of which is a phosphorescent light-emitting material.

According to the present invention, it is preferable that all of the luminescent layers include the phosphorescent light-emitting materials respectively.

Moreover, by appropriately selecting the light-emitting material, the electroluminescent device of the present invention can provide a white light electroluminescent device having a high light-emitting efficiency and a high light-emitting luminance, and an excellent chromaticity can be provided. For example, by combining a blue light-emitting material and an orange light-emitting material, a white light electroluminescent device can be obtained.

In order to provide a white light electroluminescent device having a high light-emitting efficiency, a high light-emitting luminance and an excellent chromaticity, it is preferable to appropriately select three or more kinds of light-emitting materials, the structures thereof are different from each other. It is preferable that the light-emitting materials are selected from each of blue light-emitting materials having a 400 to 500 nm light-emitting wavelength, green light-emitting materials having a 500 to 570 nm light-emitting wavelength, and red light-emitting materials having a 580 to 670 nm light-emitting wavelength. By including each of the light-emitting materials in different luminescent layer, a white light electroluminescent device can be obtained. The light-emitting materials can be appropriately selected from the examples to be described below.

The phosphorescent light-emitting material used in the present invention is not particularly limited, and it can be appropriately selected from conventionally-known materials. Examples thereof include those mentioned in [0051] to [0057] of JP-A No. 2004-221068. Among such examples, an orthometal metal complex and a phorphiline metal complex are preferable.

The above-mentioned orthometal metal complex is the generic name for the compound group mentioned in “Organic metal chemistry—basic and application—” written by Akio Yamamoto, p. 150, p. 232, Shokabo Publishing Co., Ltd., (published in 1982), “Photochemistry and photophysics of coordination compounds” written by H. Yersin, p. 71 to 77, p. 135 to 146, Springer-Verlag (published in 1987) and the like. It is advantageous to use the orthometal metal complex in the luminescent layer as the light-emitting material in terms of obtaining a high luminosity and an excellent light-emitting efficiency.

Various kinds of ligands can be used for forming the above-mentioned orthometal metal complex, and examples thereof are described in the above-mentioned articles. Among them, preferable examples of the ligands include a 2-phenyl pyridine compound, a 7,8-benzoquinoline compound, a 2-(2-thienyl) pyridine compound, a 2-(1-naphtyl) pyridine compound, a 2-phenyl quinoline compound and the like. These compounds may have a substituent in accordance with necessity. Moreover, the above-mentioned orthometal metal complex may have another ligand in addition to the above-mentioned ligand.

The orthometal metal complex used in the present invention can be synthesized by various known methods such as those mentioned in: Inorg Chem., vol. 30, p. 1685 (1991); Inorg Chem., vol. 27, p. 3464 (1988); Inorg Chem., vol. 33, p. 545(1994); Inorg. Chim. Acta, vol. 181, p. 245 (1991); J. Organomet. Chem., vol. 335, p. 293 (1987); J. Am. Chem. Soc. vol. 107, p. 1431 (1985); or the like.

Among the above-mentioned orthometal complexes, a compound which provide light emission by a triplet exciton can be preferably used in the present invention in terms of improvement of the light-emitting efficiency. Moreover, among the phorphiline complexes, a phorphiline platinum complex is preferable.

Moreover, in the present invention, in addition to the above-mentioned phosphorescence light-emitting material, a fluorescence light-emitting material can be used in a combination. Examples of the fluorescent light-emitting materials used in the invention are not particularly limited, and it can be selected arbitrarily from known materials. For example, those mentioned in [0027] of the official gazette of JP-A No. 2004-146067, [0057] of the official gazette of JP-A No. 2004-103577, or the like can be presented; however, the invention is not limited thereto.

An amount of the phosphorescent light-emitting material contained in a luminescent layer is preferably in a range of 0.1 to 40% by mass relative to a total mass of the luminescent layer, and it is more preferably in a range of 0.5 to 20% by mass.

Moreover, in the case where a fluorescent light-emitting material is contained in the luminescent layer as the light-emitting material, an embodiment in which the luminescent layer is formed only with the fluorescence light-emitting material is also preferable. Moreover, an embodiment in which the luminescent layer is formed with the host material in which a fluorescent luminescent layer is mixed is also preferred. In the case where the luminescent layer is a layer formed of the mixture of the host material and the fluorescence light-emitting material, an amount of the fluorescent light-emitting compound is preferably in a range of 0.1 to 99.9% by mass relative to a total mass of the luminescent layer, and it is more preferably in a range of 1 to 99% by mass, and it is further preferably in a range of 10 to 90% by mass.

A thickness of the luminescent layer is not particularly limited, and in general it is preferably in a range of 1 nm to 500 nm, more preferably in a range of 5 nm to 200 nm, and further preferably in a range of 10 nm to 100 nm.

Buffer Layer

The electroluminescent device of the present invention includes a buffer layer between the at least two layers of the above-mentioned luminescent layers, and it contains an organic compound (organic compound included in the buffer layer) having an energy difference Eg between the highest occupied orbit and the lowest non-occupied orbit in the buffer layer of 4.0 eV or more.

That is, examples of the configuration of the electroluminescent device of the present invention include “luminescent layer/buffer layer/luminescent layer” in the case where two luminescent layers are provided, and “luminescent layer/buffer layer/luminescent layer/buffer layer/luminescent layer” in the case where three luminescent layers are provided. It should be noted that the configuration of the electroluminescent device of the present invention is not limited thereto.

In the present invention, since a compound having a large Eg is contained in the buffer layer, transfer of the electron and the hole in the luminescent layer to another luminescent layer adjacent thereto or other layers can be efficiently inhibited, and as a result, a re-combination probability of charge in the luminescent layer can be made higher so that the light-emitting efficiency can be improved.

Moreover, in the case where two or more luminescent layers are provided, a problem of the chromaticity deterioration due to the light emission of the adjacent luminescent layers caused when an electron or a hole moves from a luminescent layer to another adjacent luminescent layer is presumed. However, since the present invention provides a buffer layer between the different luminescent layers and the buffer layer contains a compound having a large Eg, movement of the electron or the hole to another adjacent luminescent layer can be efficiently restrained so that the chromaticity deterioration can be prevented.

That is, since the present invention provides a buffer layer containing an organic compound having the energy difference Eg of the highest occupied orbit and the lowest non occupied orbit of 4.0 eV or more between the different luminescent layers, the light-emitting luminance of each luminescent layer and the light-emitting efficiency can be improved. Further, the present invention enables restraining the chromaticity deterioration, the light emission of a desired chromaticity can be achieved. As a result, the electroluminescent device having an extremely high light-emitting efficiency and an excellent chromaticity can be obtained.

The lowest excited triplet energy level (Ti) of the organic compound included in the buffer layer is preferably 2.7 eV or more, and it is more preferably 2.8 eV or more.

By including the organic compound having 2.7 eV or more T1 in the buffer layer, the exciton diffusion from a light-emitting material to the organic compound can be restrained, and therby, the light-emitting efficiency is further preferably improved.

In particular, in the case where the light-emitting material is a blue phosphorescent light-emitting material, since T1 thereof is as large as approximately 2.6 eV, T1 of the organic compound is preferably larger than that, that is, 2.7 eV or more, in order to restrain the diffusion of the triplet exciton. By including the organic compound having 2.7 eV or more T1 in the buffer layer, the light-emitting efficiency can further be improved even in the case where a blue phosphorescent light-emitting material is used.

In the present invention, T1 of the organic compound included in the buffer layer is 2.7 eV or more, and the upper limit value thereof is preferably 3.7 eV.

The organic compound included in the above-mentioned buffer layer is not particularly limited as long as it is a compound satisfying the above-mentioned conditions. From the viewpoint of the stability, an aromatic hydrocarbon is preferred, and a compound represented by the following Formula (1) or Formula (3) is more preferable.
L-(Ar)ₘ Formula (1)

In Formula (1), Ar is a group represented by the following Formula (2), L is a benzene skeleton having a valence of 3 or more, and m is an integer of 3 or more.

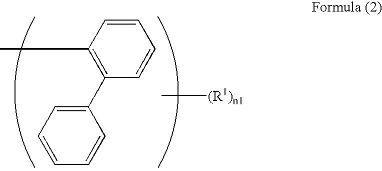

In Formula (2), R¹ is a substituent, and in the case where R¹ is present in a plurality, they may either be the same or different from each other. n1 is an integer from 0 to 9.

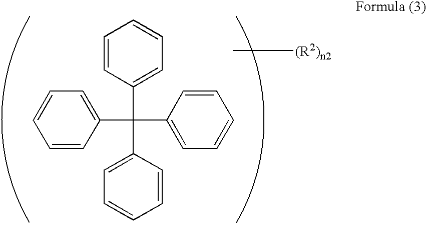

In Formula (3), R² is a substituent, and in the case where R² is present in a plurality, they may either be the same or different from each other. n2 is an integer from 0 to 20.

First, Formula (1) will be explained in detail.

L included in Formula (1) is a benzene skeleton having a valence of 3 or more. Ar is a group represented by Formula (2), and m is an integer of 3 or more.

The benzene skeleton represented by L is preferably a trivalent benzene skeleton or a tetravalent benzene skeleton.

m is preferably 3 or more and 6 or less, and it is further preferably 3 or 4.

Next, the group represented by Formula (2) will be explained.

R¹ included in Formula (2) is a substituent. Examples of the substituent include an alkyl group (preferably having 1 to 30 carbon atoms, more preferably having 1 to 20 carbon atoms, and particularly preferably having 1 to 10 carbon atoms, and examples thereof include a methyl group, an ethyl group, an iso-propyl group, a tert-butyl group, a n-octyl group, a n-decyl group, a n-hexadecyl group, a cyclopropyl group, a cyclopentyl group, a cyclohexyl group and the like), an alkenyl group (preferably having 2 to 30 carbon atoms, more preferably having 2 to 20 carbon atoms, and particularly preferably having 2 to 10 carbon atoms, and examples thereof include a vinyl group, an allyl group, a 2-butenyl group, a 3-pentenyl group, and the like), an alkynyl group (preferably having 2 to 30 carbon atoms, more preferably having 2 to 30 carbon atoms, and particularly preferably having 2 to 10 carbon atoms, and examples thereof include a propalgyl group, a 3-pentinyl group and the like), an aryl group (preferably having 6 to 30 carbon atoms, more preferably having 6 to 20 carbon atoms, and particularly preferably having 6 to 12 carbon atoms, and examples thereof include a phenyl group, a p-methyl phenyl group, a naphthyl group, an anthranyl group and the like),

an amino group (preferably having 0 to 30 carbon atoms, more preferably having 0 to 20 carbon atoms, and particularly preferably having 0 to 10 carbon atoms, and examples thereof include an amino group, a methyl amino group, a dimethyl amino group, a diethyl amino group, a dibenzyl amino group, a diphenyl amino group, a ditolyl amino group and the like), an alkoxy group (preferably having 1 to 30 carbon atoms, more preferably having 1 to 20 carbon atoms, and particularly preferably having 1 to 10 carbon atoms, and examples thereof include a methoxy group, an ethoxy group, a butoxy group, a 2-ethyl hexyloxy group and the like), an aryloxy group (preferably having 6 to 30 carbon atoms, more preferably having 6 to 20 carbon atoms, and particularly preferably having 6 to 12 carbon atoms, and examples thereof include a phenyloxy group, a 1-naphtyloxy group, a 2-naphthyloxy group and the like), a heteroaryloxy group (preferably having 1 to 30 carbon atoms, more preferably having 1 to 20 carbon atoms, and particularly preferably having 1 to 12 carbon atoms, and examples thereof include a pyridyloxy group, a pyradyloxy group, a pyrymidyloxy group, a quinolyloxy group and the like), an acyl group (preferably having 1 to 30 carbon atoms, more preferably having 1 to 20 carbon atoms, and particularly preferably having 1 to 12 carbon atoms, and examples thereof include an acetyl group, a benzoyl group, a formyl group, a pivaloyl group and the like), an alkoxy carbonyl group (preferably having 2 to 30 carbon atoms, more preferably having 2 to 20 carbon atoms, and particularly preferably having 2 to 12 carbon atoms, and examples thereof include a methoxy group, a carbonyl group, an ethoxy carbonyl group and the like), an aryloxy carbonyl group (preferably having 7 to 30 carbon atoms, more preferably having 7 to 20 carbon atoms, and particularly preferably having 7 to 12 carbon atoms, and examples thereof include a phenyloxy carbonyl group and the like),

an acyloxy group (preferably having 2 to 30 carbon atoms, more preferably having 2 to 20 carbon atoms, and particularly preferably having 2 to 10 carbon atoms, and examples thereof include an acetoxy group, a benzoyloxy group and the like), an acyl amino group (preferably having 2 to 30 carbon atoms, more preferably having 2 to 20 carbon atoms, and particularly preferably having 2 to 10 carbon atoms, and examples thereof include an acetyl amino group, a benzoyl amino group and the like), an alkoxy carbonyl amino group (preferably having 2 to 30 carbon atoms, more preferably having 2 to 20 carbon atoms, and particularly preferably having 2 to 12 carbon atoms, and examples thereof include a methoxy carbonyl amino group and the like), an aryloxy carbonyl amino group (preferably having 7 to 30 carbon atoms, more preferably having 7 to 20 carbon atoms, and particularly preferably having 7 to 12 carbon atoms, and examples thereof include a phenyloxy carbonyl aminogroup and the like),

a sulfonyl amino group (preferably having 1 to 30 carbon atoms, more preferably having 1 to 20 carbon atoms, and particularly preferably having 1 to 12 carbon atoms, and examples thereof include a methane sulfonyl amino group, a benzene sulfonyl amino group and the like), a sulfamoyl group (preferably having 0 to 30 carbon atoms, more preferably having 0 to 20 carbon atoms, and particularly preferably having 0 to 12 carbon atoms, and examples thereof include a sulfamoyl group, a methyl sulfamoyl group, a dimethyl sulfamoyl group, a phenyl sulfamoyl group and the like), a carbamoyl group (preferably having 1 to 30 carbon atoms, more preferably having 1 to 20 carbon atoms, and particularly preferably having 1 to 12 carbon atoms, and examples thereof include a carbamoyl group, a methyl carbamoyl group, a diethyl carbamoyl group, a phenyl carbamoyl group and the like), an alkyl thio group (preferably having 1 to 30 carbon atoms, more preferably having 1 to 20 carbon atoms, and particularly preferably having 1 to 12 carbon atoms, and examples thereof include an a methyl thio group, an ethyl thio group and the like), an aryl thio group (preferably having 6 to 30 carbon atoms, more preferably having 6 to 20 carbon atoms, and particularly preferably having 6 to 12 carbon atoms, and examples thereof include a phenyl thio group and the like), a heteroaryl thio group (preferably having 1 to 30 carbon atoms, more preferably having 1 to 20 carbon atoms, and particularly preferably having 1 to 12 carbon atoms, and examples thereof include a pyridyl thio group, a 2-benzimizolyl thio group, a 2-benzoxazoyl thio group, a 2-benzthiazolyl thio group and the like),

a sulfonyl group (preferably having 1 to 30 carbon atoms, more preferably having 1 to 20 carbon atoms, and particularly preferably having 1 to 12 carbon atoms, and examples thereof include a mecyl group, a tocyl group and the like), a sulfinyl group (preferably having 1 to 30 carbon atoms, more preferably having 1 to 20 carbon atoms, and particularly preferably having 1 to 12 carbon atoms, and examples thereof include a methane sulfinyl group, a benzene sulfinyl group and the like), a ureido group (preferably having 1 to 30 carbon atoms, more preferably having 1 to 20 carbon atoms, and particularly preferably having I to 12 carbon atoms, and examples thereof include a ureido group, a methyl ureido group, a phenyl ureido group and the like), an amide phosphate group (preferably having 1 to 30 carbon atoms, more preferably having 1 to 20 carbon atoms, and particularly preferably having 1 to 12 carbon atoms, and examples thereof include a diethyl amide phosphate group, a phenyl amide phosphate group and the like),

a hydroxyl group, a mercapto group, a halogen atom (for example, a fluorine atom, a chlorine atom, a bromine atom, an iodine atom or the like), a cyano group, a sulfo group, a carboxyl group, a nitro group, a hydroxamic acid group, a sulfino group, a hydrodino group, an imino group, a hetero cyclic group (preferably having 1 to 30 carbon atoms, and more preferably having 1 to 12 carbon atoms; examples of a hetero atom therein include a nitrogen atom, an oxygen atom, a sulfur atom and the like; and specific examples thereof include an imidazolyl group, a pyridyl group, a quinolyl group, a furyl group, a thienyl group, a piperidyl group, a morpholyno group, a benzoxazoly group, a benzimidazoyl group, a benzthiazolyl group, a carbazolyl group, an azepynyl group and the like ), a silyl group (preferably having 3to 40 carbon atoms, more preferably having 3 to 30 carbon atoms, and particularly preferably having 3 to 24 carbon atoms, and examples thereof include a trimethyl silyl group, a triphenyl silyl group and the like ) and the like.

Preferable examples of the substituent represented by R¹ of Formula (2) include an alkyl group having 1 to 20 carbon atoms, an alkenyl group having 2 to 20 carbon atoms, an alkynyl group having 2 to 20 carbon atoms, an aryl group having 6 to 30 carbon atoms, an amino group having 0 to 20 carbon atoms, an alkoxy group having 1 to 20 carbon atoms, an aryloxy group having 6 to 30 carbon atoms, an acyl group having 1 to 20 carbon atoms, an alkoxy carbonyl group having 2 to 20 carbon atoms, an acyloxy group having 2 to 20 carbon atoms, an aryloxy carbonyl group having 7 to 30 carbon atoms, an alkyl thio group having 1 to 20 carbon atoms, an aryl thio group having 6 to 30 carbon atoms, a heterocyclic group having 5 to 30 carbon atoms, and a silyl group having 3 to 30 carbon atoms. More preferable examples thereof include an alkyl group having 1 to 20 carbon atoms, an aryl group having 6 to 30 carbon atoms, an amino group having 0 to 20 carbon atoms, an alkoxy group having 1 to 20 carbon atoms, an aryloxy group having 6 to 30 carbon atoms, an acyl group having 1 to 20 carbon atoms, an alkyl thio group having 1 to 20 carbon atoms, and a silyl group having 3 to 30 carbon atoms. Further preferable examples thereof include an alkyl group having 1 to 20 carbon atoms, an aryl group having 6 to 30 carbon atoms, an amino group having 0 to 20 carbon atoms, an alkoxy group having 1 to 20 carbon atoms, an acyl group having 1 to 20 carbon atoms, an alkyl thio group having 1 to 20 carbon atoms, and a silyl group having 3 to 30 carbon atoms.

In the case where R¹ is present in plurality, they may either be the same or different from each other, and they may be bonded with each other so as to form a ring. Moreover, R¹ may further have a substitutent.

n1 is an integer from 0 to 9. n1 is preferably an integer from 0 to 6, and it is further preferably 0 to 3.

Examples of preferable combination of the moieties represented by L, Ar or m in the compound represented by Formula (1) is the combinations of each of the above-described preferable examples of the respective moieties.

Subsequently, Formula (3) will be explained.

R² in Formula (3) is a substituent. The substituent represented by R² is similar to the above-mentioned substituent represented by R¹ including the preferable embodiments, and preferable examples thereof are also similar to those of the substituent represented by R¹.

n2 is an integer from 0 to 20. The preferable range of n2 is from 0 to 10, and it is further preferably 0 to 5.

The compound examples of Formula (1) or Formula (3) will be shown below; however, the present invention is not limited thereto.

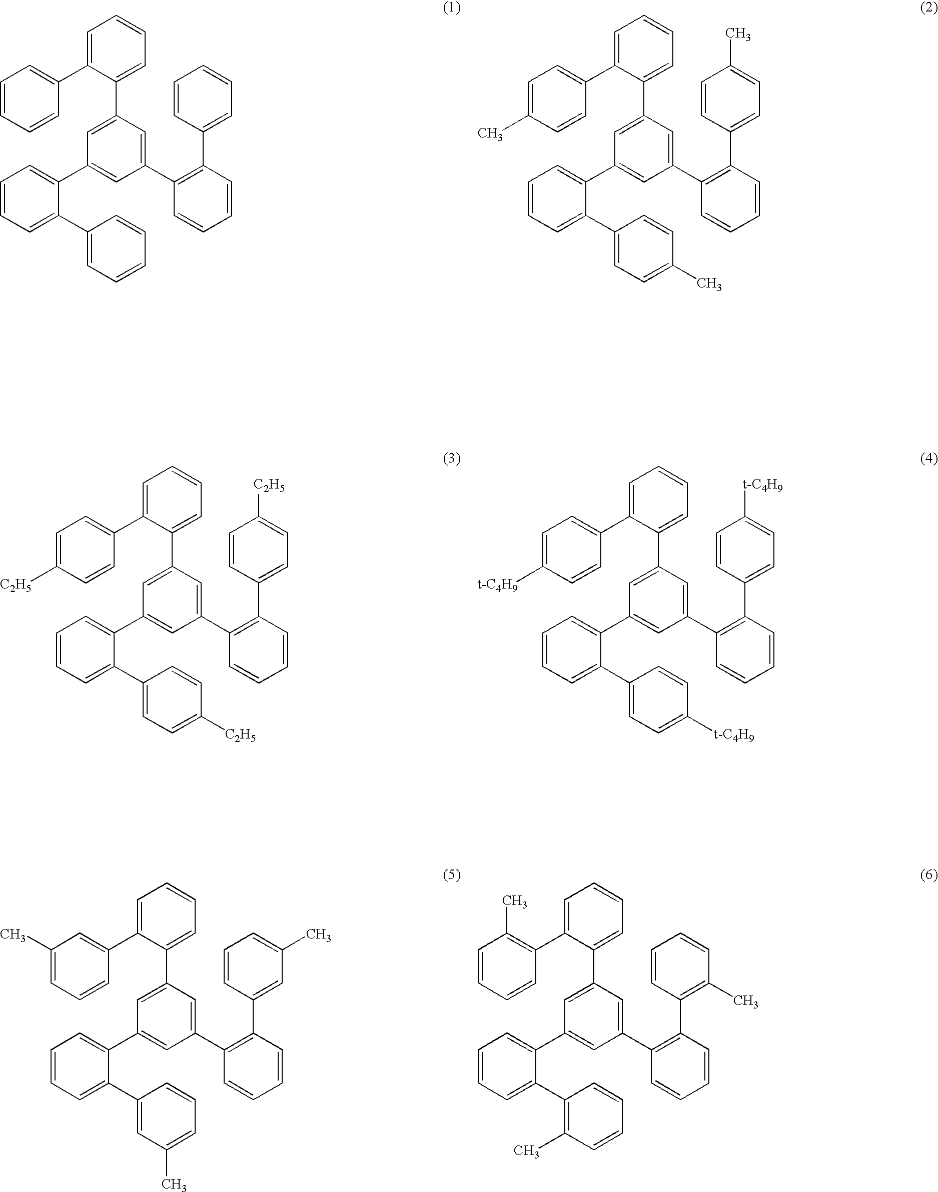

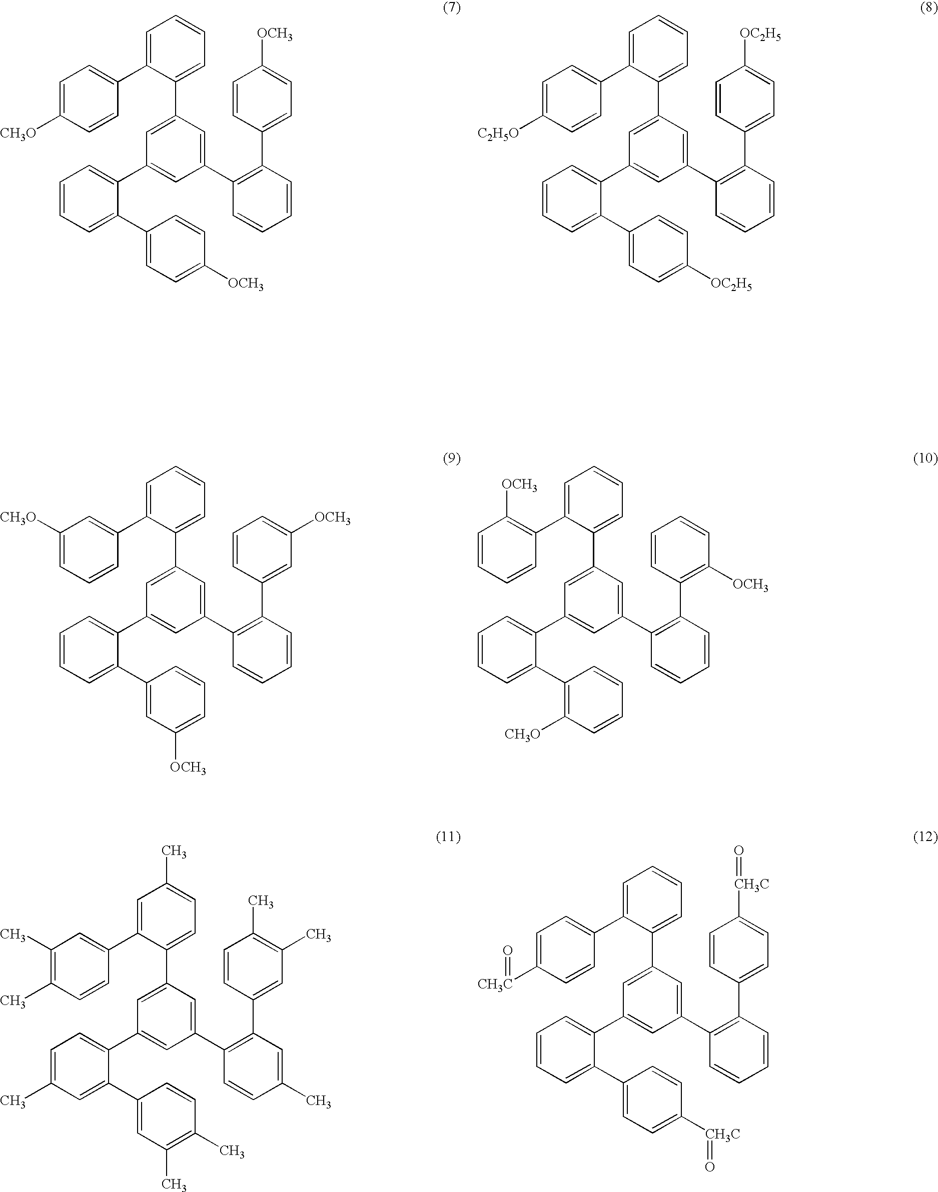

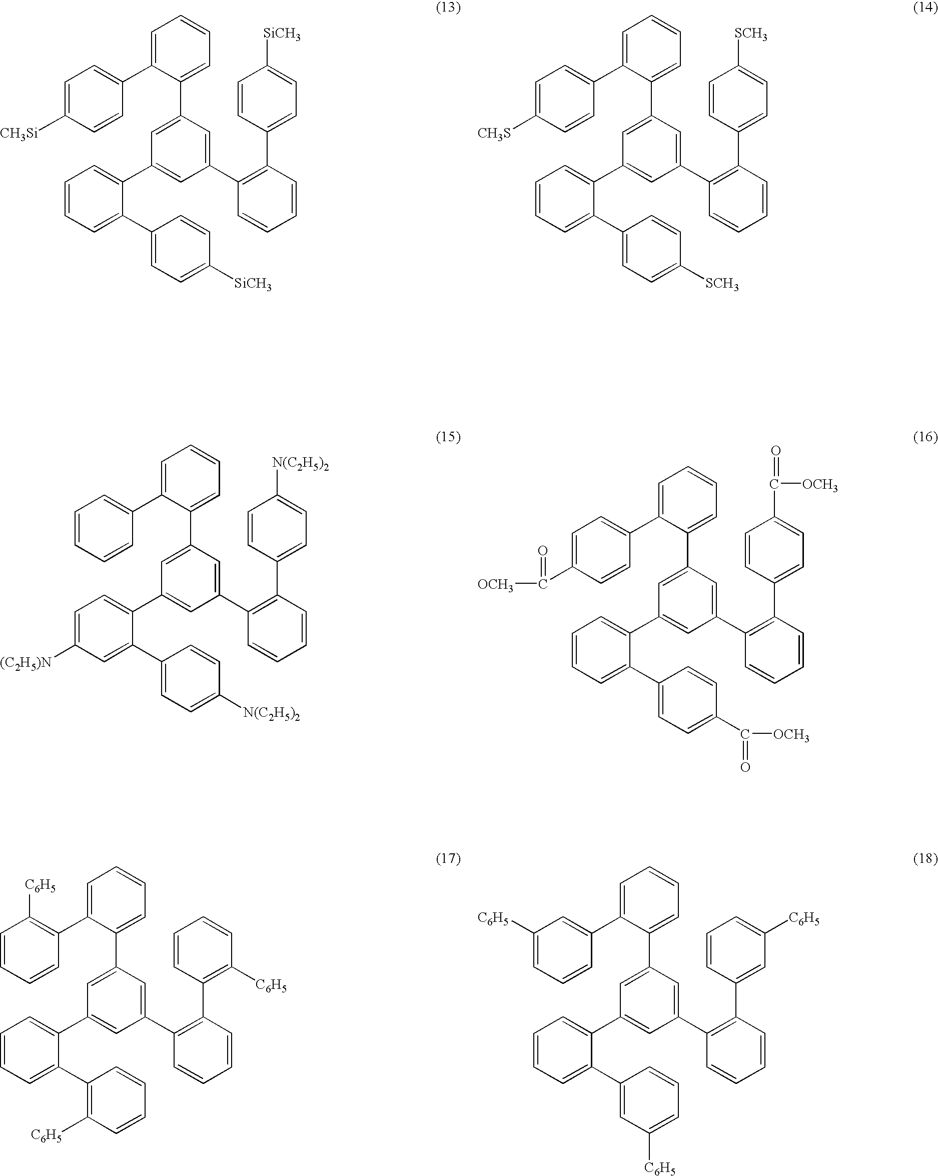

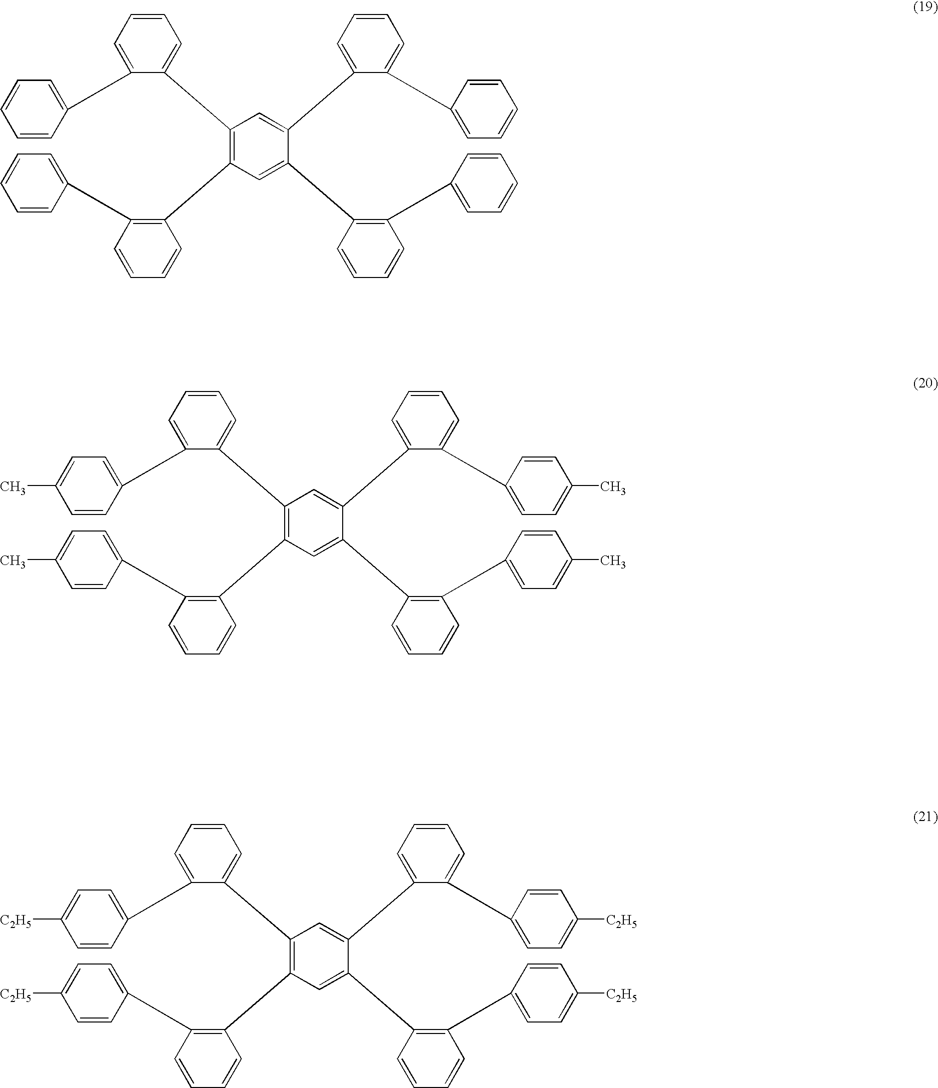

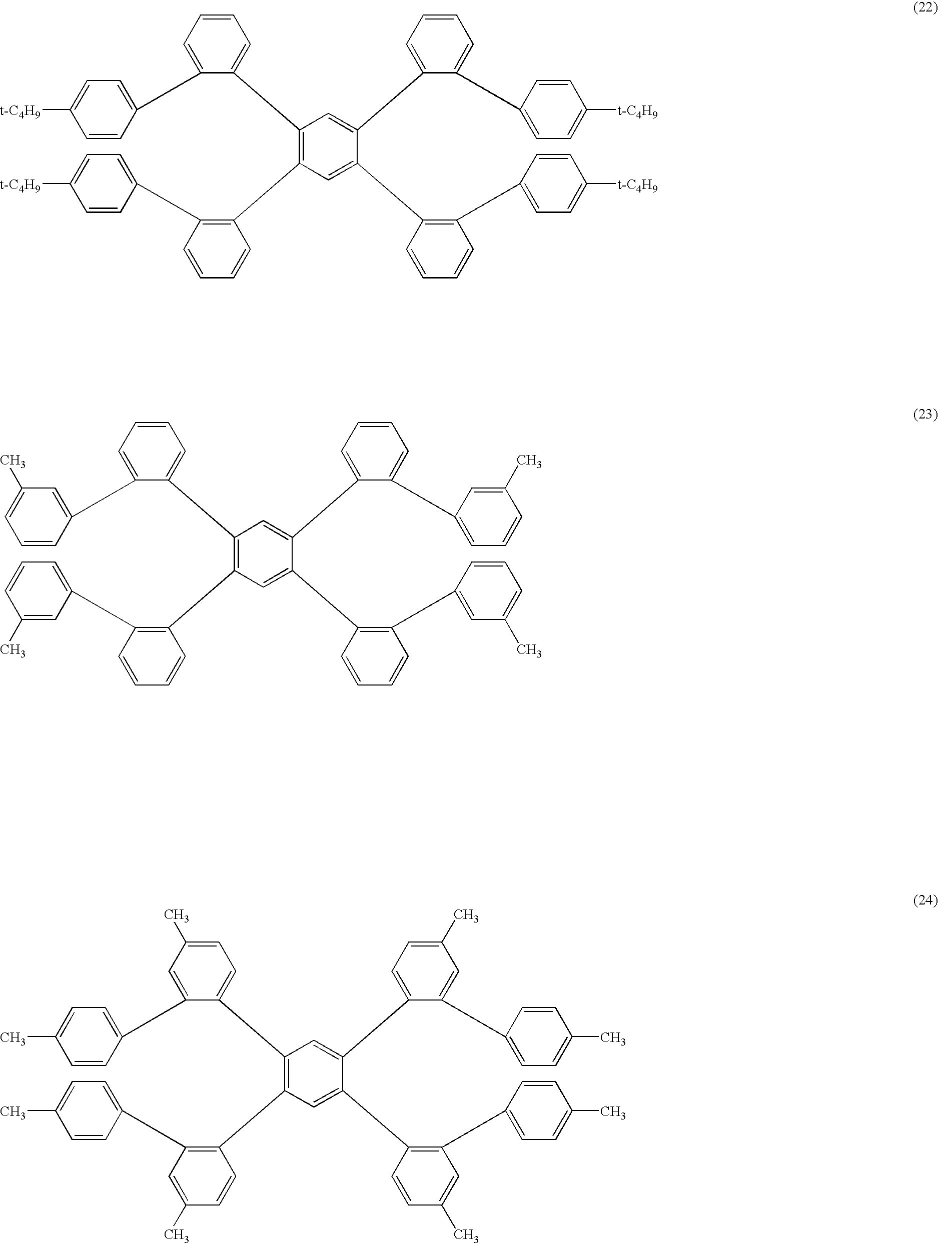

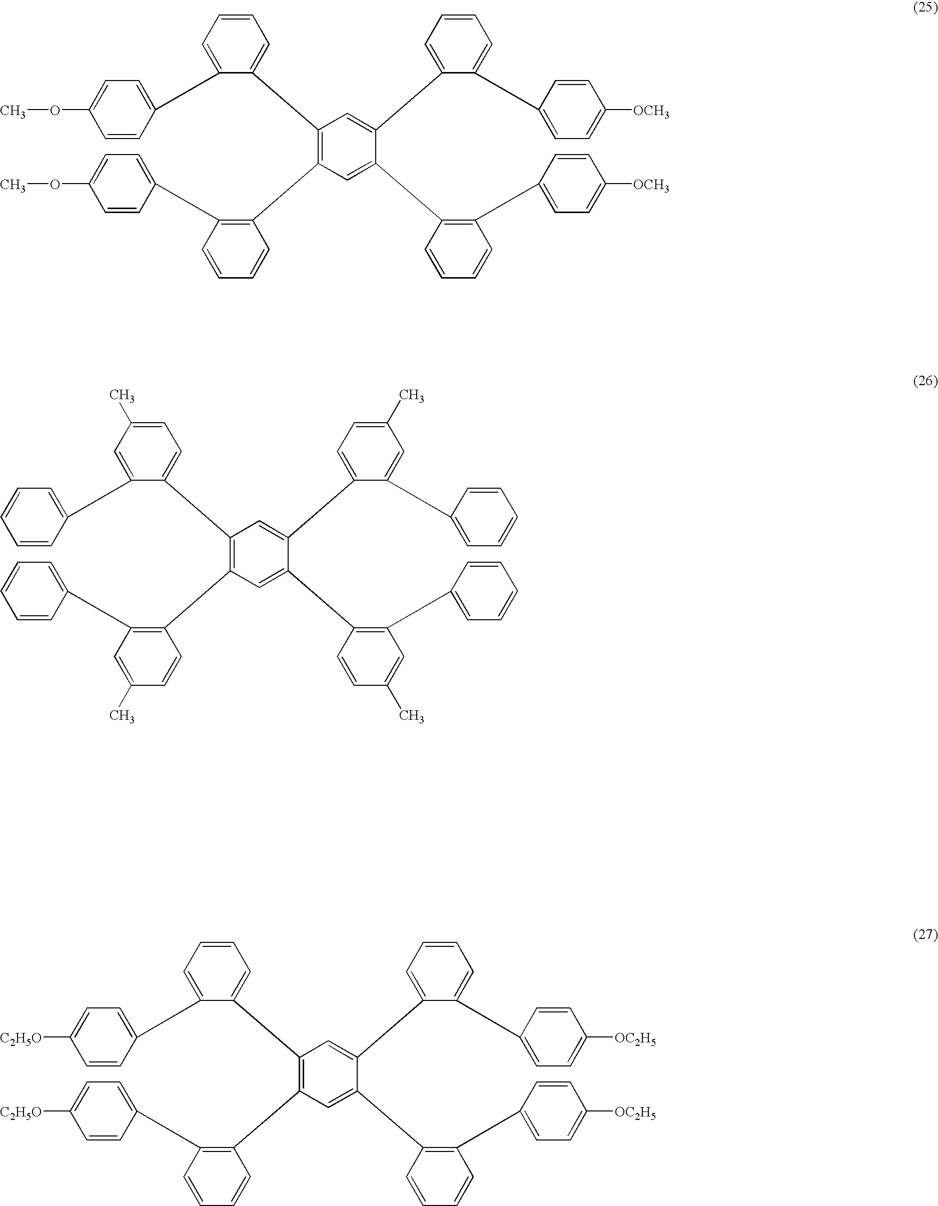

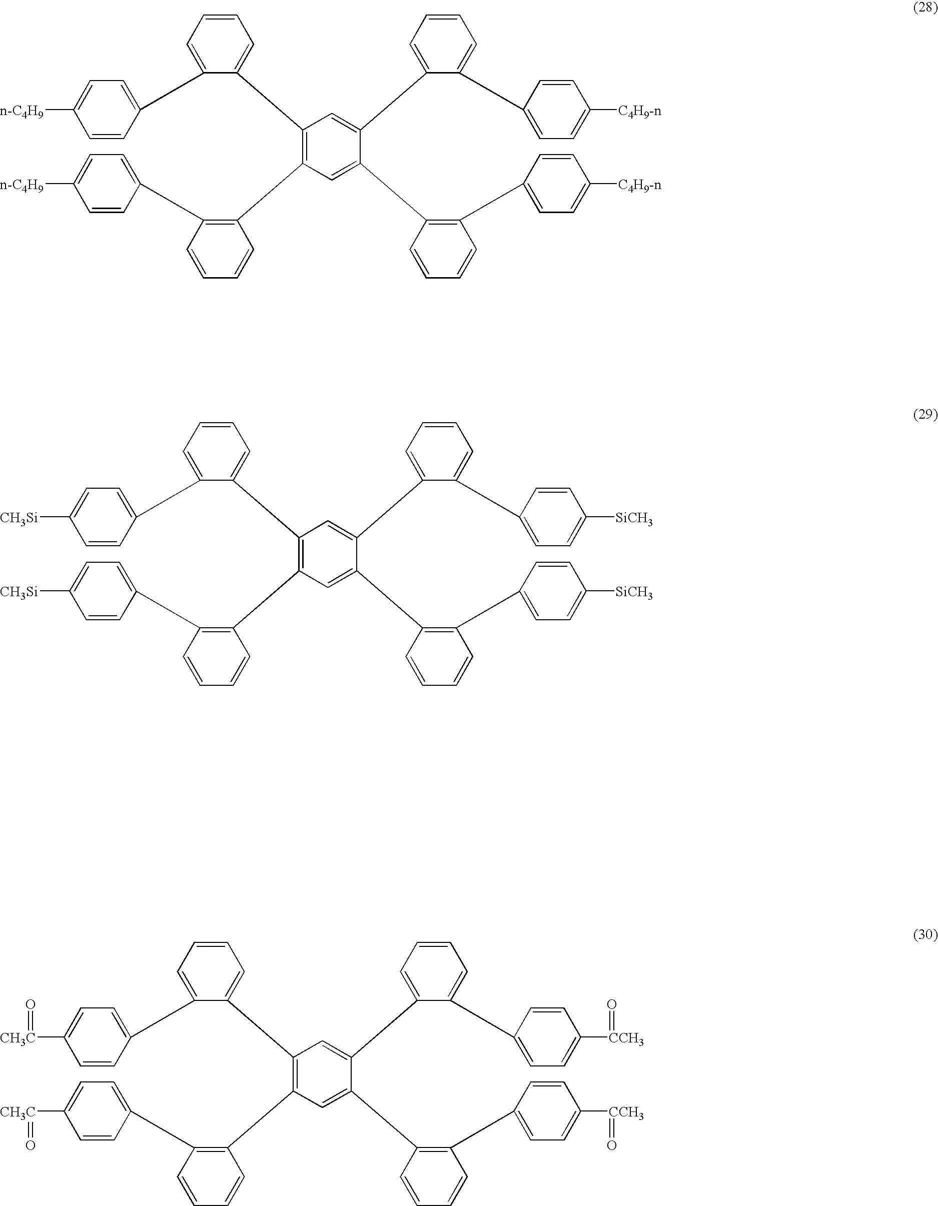

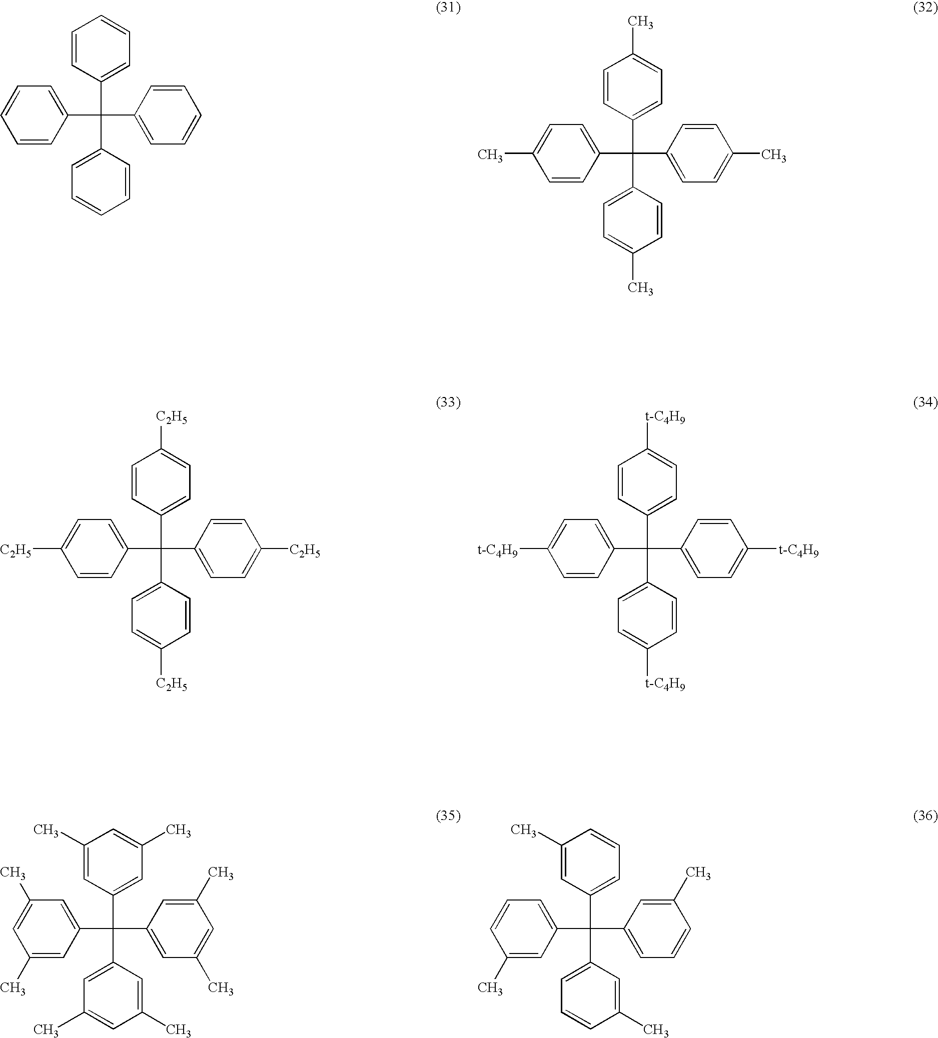

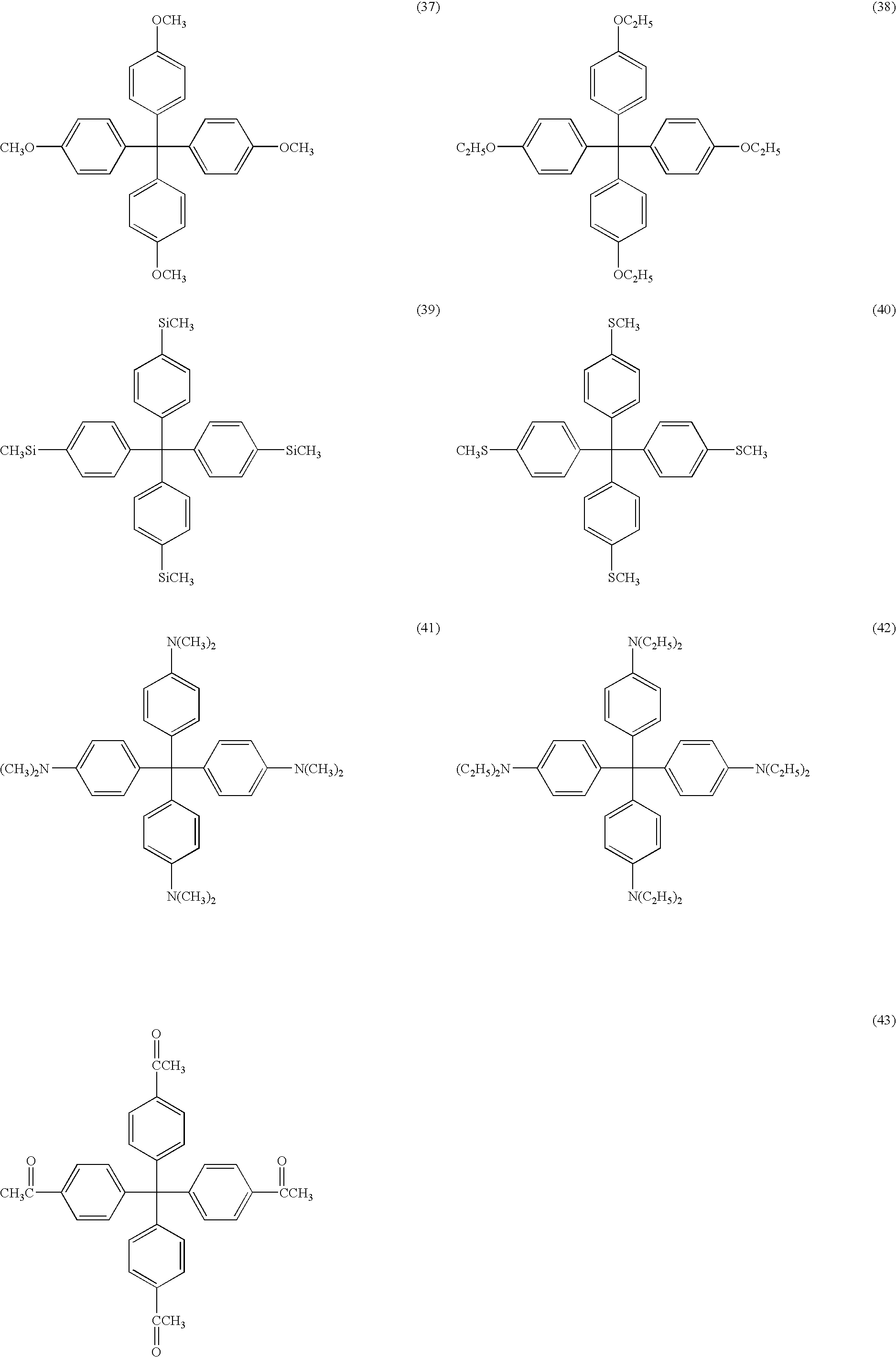

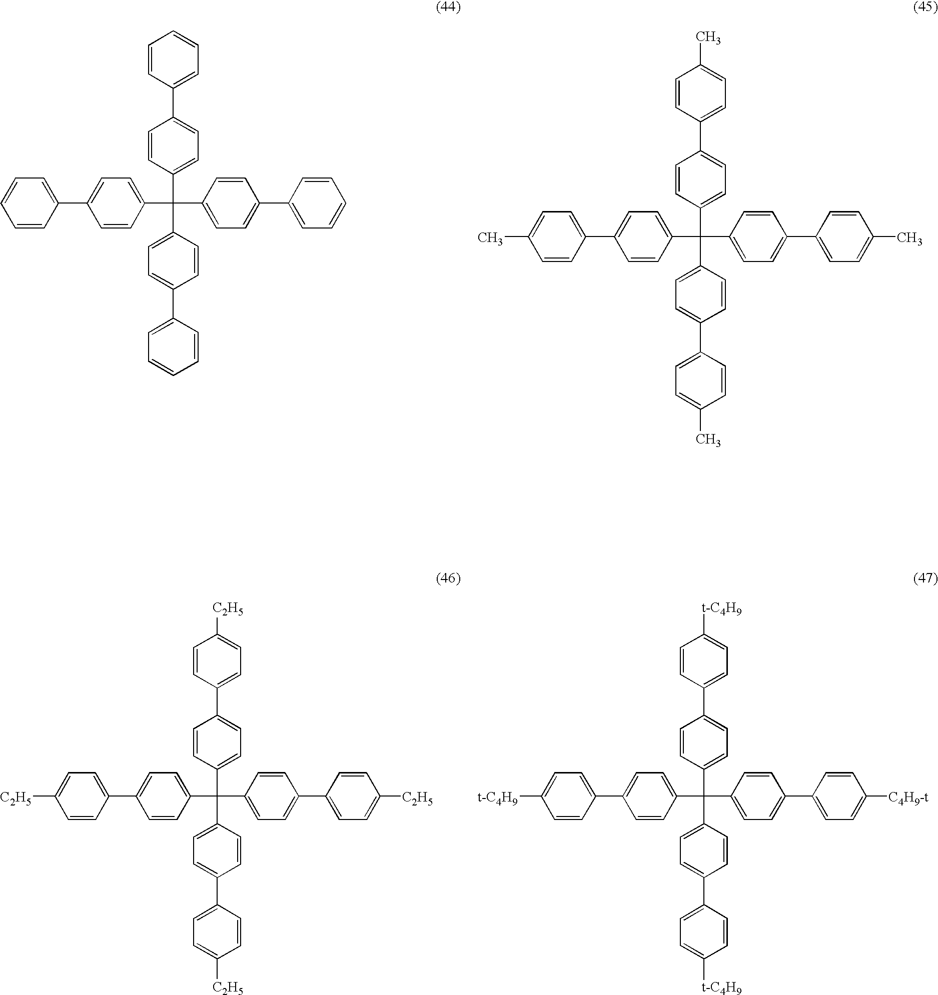

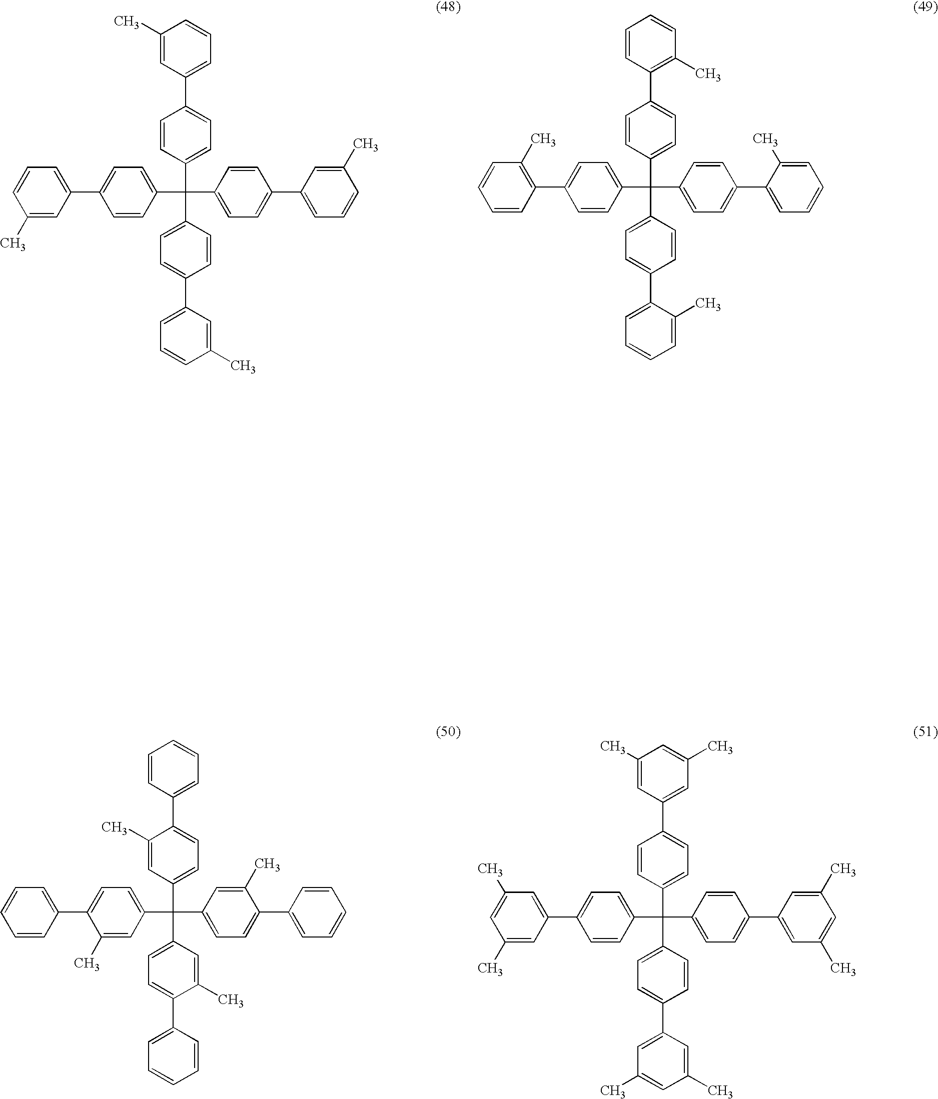

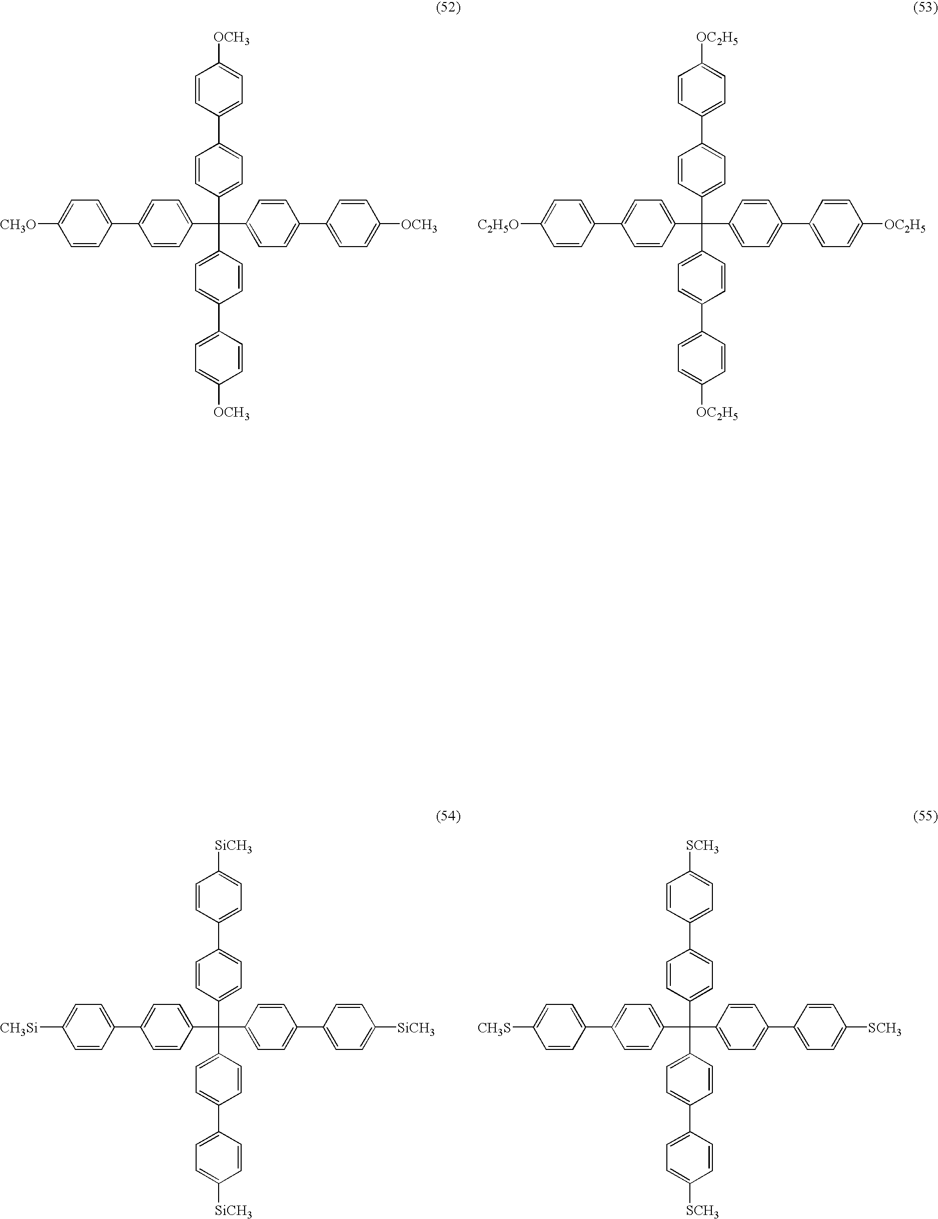

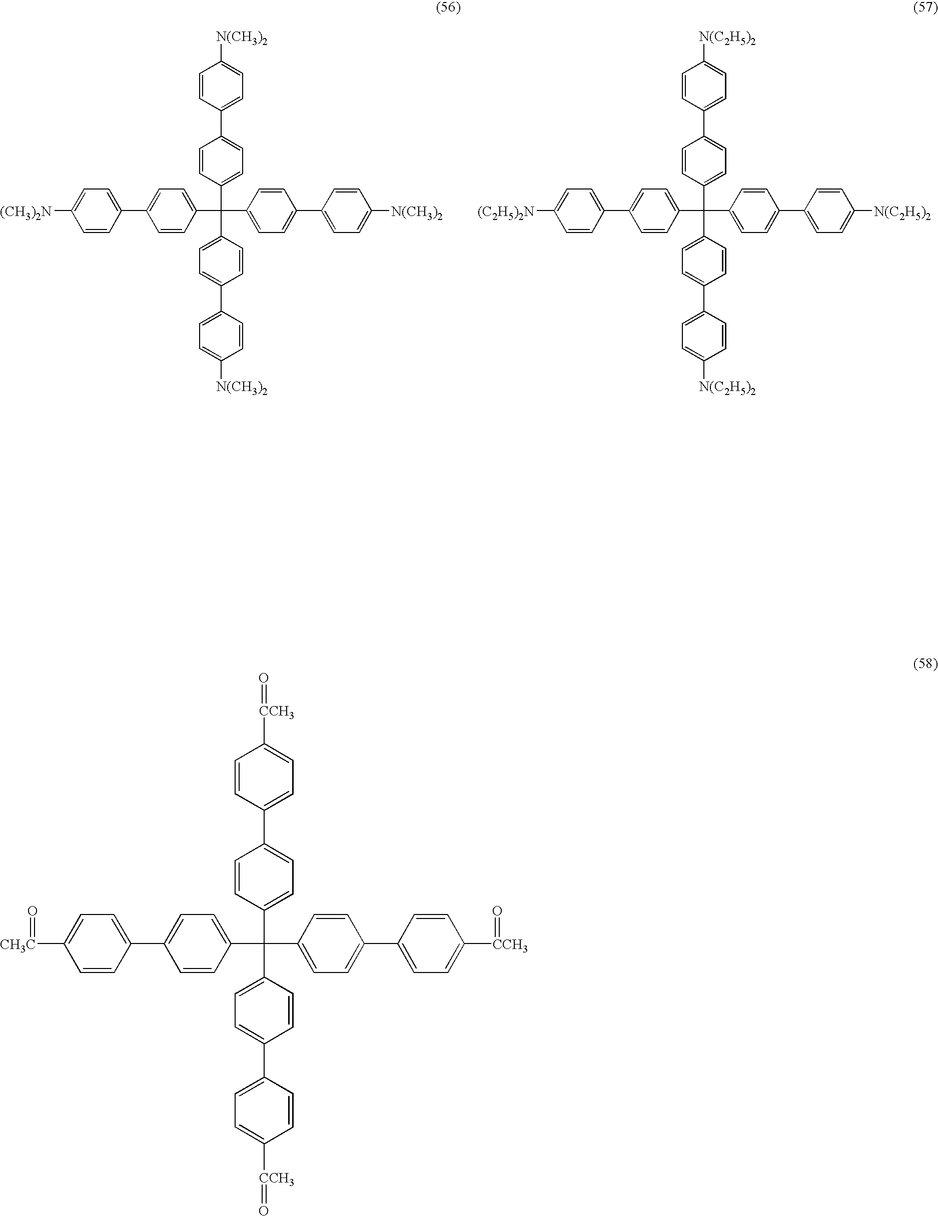

The organic compound included in the buffer layer may either be of one kind alone or two or more kinds. A content (amount) of the organic compound included in the buffer layer is preferably 2% by mass or more and 99.5% by mass or less, and it is further preferably 5% by mass or more and 99% by mass or less, relative to a total mass of the buffer layer.

Moreover, in the case where plurality of the buffer layers are included in the device of the invention (that is, in the case where three or more luminescent layers are provided), the plural buffer layers included may either be layers having the same constituent components or be layers having different constituent components.

Moreover, it is also preferable that the buffer layer used the invention includes a hole transporting material or an electron transporting material in order to set a driving voltage of the electroluminescent device in an optimum range.

The material used as the hole transporting material or the electron transporting material included in the buffer layer is not particularly limited, and it can be arbitrarily selected from conventionally-known materials. For example, the materials mentioned in the official publication documents of the patents to be described later can be used.

Each of contents (amounts) of the hole transporting material and the electron transporting material in a buffer layer is preferably in a range of 0.5 to 98% by mass, and more preferably in a range of 1 to 95% by mass, relative the a total mass of the buffer layer.

A film thickness of the buffer layer in the present invention is preferably in a range of 0.5 to 20 nm, more preferably in a range of 0.5 to 15 nm, and particularly preferably in a range of 0.5 to 10 nm, in order to set the driving voltage of the electroluminescent device in an optimum range.

Examples of the other constituent elements used in the organic electroluminescent device of the present invention such as a supporting substrate, an electrode, respective organic compound layers and the other layers include those described in [0013] to [0082] of JP-A No. 2004-221068, [0017] to [0091] of JP-A No. 2004-214178, [0024] to [0035] of JP-A No. 2004-146067, [0017] to [0068] of JP-A No. 2004-103577, [0014] to [0062] of JP-A No. 2003-323987, [0015] to [0077] of JP-A No. 2002-305083, [0008] to [0028] of JP-A No. 2001-172284, [0013] to [0075] of JP-A No. 2000-186094, [0016] to [0118] of Japanese Patent Application National Publication (Laid-Open) No. 2003-515897 and the like. It should be noted that the invention is not limited thereto.

The hole injecting layer or the hole transporting layer of the organic electroluminescent device of the invention may contain an electron-acceptive dopant in order to control a balance of electric charge in the device and a driving voltage of the device. Any materials such as an organic compound or an inorganic compoud can be used as the electron-acceptive dopant as long as it is electron-acceptive and capable of oxidizing organic compounds.

Specific preferable examples thereof among inorganic compounds include metal oxides such as ferric chloride, aluminum chloride, gallium chloride, indium chloride, antimony pentachloride or the like.

Specific preferable examples thereof among organic compounds include a compound having a nitro group, a halogen, a cyano group, a trifluoromethyl group or the like as a substituent thereof, a quinone compound, an acid anhydride compound, and fullerene. Specific preferable examples thereof further include compounds described in JP-A Nos. 6-212153, 11-111463, 11-25106, 2000-196140, 2000-286054, 2000-31558, 2001-102175, 2001-160493, 2002-252085, 2002-56985, 2003-157981, 2003-217862, 2003-229278, 2004-342614, 2005-72012, 2005-166637, and 2005-209643.

These electron-acceptive dopant may be used singly or in combination of two or more thereof. An amount of the electron-acceptive dopant used in the hole injecting layer or the hole transporting layer may vary depending on a material thereof. It is preferably in a range of 0.01 to 50% by mass, more preferably in a range of 0.05 to 20% by mass, and further preferably in a range of 0.1 to 10% by mass relative to materials constituting the hole transporting layer.

The electron injecting layer or the electron transporting layer of the organic electroluminescent device of the invention may contain an electron-donative dopant in order to control a balance of electric charge in the device and a driving voltage of the device. Any materials such as an organic compound or an inorganic compound can be used as the electron-donative dopant as long as it is electron-donative and capable of reducing organic compounds, and specific preferable examples thereof include alkali metals such as lithium, alkaline earth metals such as magnecium, transition metals including rare earth metals, reductive organic compounds and the like. Preferable examples of a metal which can be used as the electron-donative dopant include those having work function of 4.2 eV or less, and specific examples thereof include Li, Na, K, Be, Mg, Ca, Sr, Ba, Y, Cs, La, Sm, Gd and Yb. Examples of a reductive organic compound include a nitrogen-containing compound, a sulfur-containing compound and a phosphor-containing compound. Specific preferable examples thereof further include materials described in JP-A Nos. 6-212153, 2000-196140, 2003-68468, 2003-229278, and 2004-342614.

These electron-donative dopant may be used singly or in combination of two or more thereof. An amount of the electron-donative dopant used in the electron injecting layer or the electron transporting layer may vary depending on a material thereof. It is preferably in a range of 0.1 to 99% by mass, more preferably in a range of 1.0 to 80% by mass, and further preferably in a range of 2.0 to 70% by mass relative to materials constituting the electron transporting layer.

According to the organic electroluminescent device of the present invention, the light emission can be obtained by applying a direct current (, which may include an alternative current component in accordance with necessity) voltage (in general in a range of 2 volts to 15 volts) or a direct current between the anode and the cathode.

Examples of a driving method for the organic electroluminescent device of the present invention include those described in JP-A Nos. 2-148687, 6-301355, 5-29080, 7-134558, 8-234685, 8-241047, Japanese Patent No. 2784615, U.S. Pat. Nos. 5,828,429, 6,023,308 and the like.

### EXAMPLES

Hereinafter, the organic EL device of the present invention is specifically described with reference to Examples. However, the Examples should not be construed as limiting the invention.

### Comparative Example 1

A glass substrate having a 0.5 mm thickness and an ITO film of a 2.5 cm square size (manufactured by Geomatic Co., Ltd., surface resistance: 10 Ω/□) was placed in a washing container so as to have an ultrasonic wave washing with a 2-propanol, then a UV-ozone process was carried out for 30 minutes. a PEDOT-PSS (polyethylene dioxy thiophene-polystyrene sulfonic acid doped substance) solution (trade name: BAYTRON P, manufactured by Bayer Corporation) was spin coated on the ITO substrate which was underwent the UV-ozone process (4000 rpm, 40 sec), and it was vacuum dried at 120° C. for 10 minutes. A film thickness of the PEDOT-PSS layer was 40 nm.

The following organic compound layers were deposited successively by the vacuum deposition method onto the PEDOT-PSS layer.

The deposition rate used in the Example was 0.2 nm/second unless otherwise specified. The deposition rate was measured using a quarts oscillator. The film thicknesses mentioned below were also measured using the quarts oscillator.

A hole transporting layer was formed by depositing NPD so that a film thickness thereof became 40 nm.

A first luminescent layer was formed by depositing a mixture containing 92% by mass of CBP and 8% by mass of FIrpic so that a film thickness thereof became 10 mn.

A second luminescent layer was formed by depositing a mixture containing 92% by mass of CBP and 8% by mass of Btp₂Ir(acac) so that a film thickness thereof became 10 nm.

A third luminescent layer was formed by depositing a mixture containing a mixture containing 92% by mass of CBP and 8% by mass of Ir(ppy)₃ so that a film thickness thereof became 10 mn.

Further, an electron transporting layer was formed by depositing BCP so that a film thickness thereof became 10 nm.

T1s of the light-emitting materials used in respective luminescent layers are in the followings.
T1 of FIrpic: 2.7 eV
T1 of Btp₂Ir(acac): 2.0 eV
Ti of Ir(Ppy)₃: 2.5 eV

Chemical structures of PEDOT-PSS, NPD, CBP, FIrpic, Btp₂Ir(acac), Ir(Ppy)₃ and BCP used in the above are in the followings.

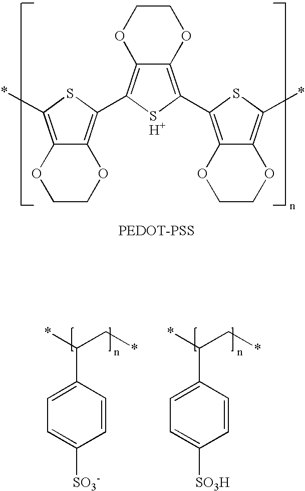

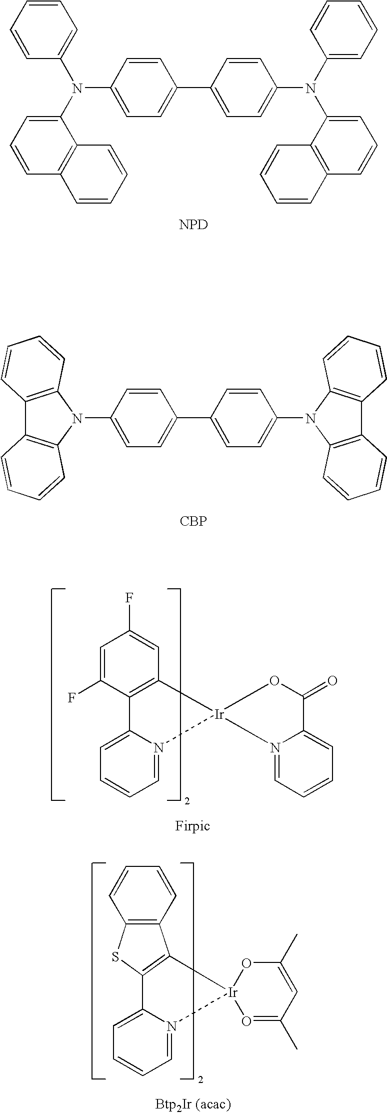

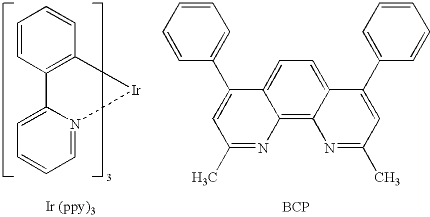

Subsequently, with a patterned mask (mask for forming a 2 mm×2 mm light-emitting region) placed on the electron transporting layer, a lithium fluoride was deposited by a 0.1 nm/second deposition rate so as to provide an electron injection layer having a thickness of 0.5 nm. Finally, a metal aluminum was deposited so as to have a thickness of 100 nm in order to provide a cathode.

It was placed in a glove box substituted with an argon gas without contacting with the atmosphere and sealed with a stainless steel sealing can and an ultraviolet ray hardening type adhesive (trade name: XNR5516HV, manufactured by Nagase-CIBA Ltd.).

As mentioned above, an electroluminescent device of Comparative example 1 was produced.

### Example 1

An electroluminescent device of Example 1 was produced in the same manner as in Comparative example 1, except that the conformation of the organic compound layers are changed as follows.

A hole transporting layer was formed by depositing NPD so that a film thickness thereof become 40 nm.

A first luminescent layer was formed by depositing a mixture containing 92% by mass of CBP and 8% by mass of FIrpic so that a film thickness thereof became 10 nm.

A first buffer layer was formed by depositing a mixture containing 50% by mass of the compound A and 50% by mass of CBP so that a film thickness thereof became 3 nm.

A second luminescent layer was formed by depositing a mixture containing 92% by mass of CBP and 8% by mass of Btp₂Ir(acac) so that a film thickness thereof became 10 nm.

A second buffer layer was formed by depositing a mixture containing 50% by mass of the compound A and 50% by mass of CBP so that a film thickness thereof became 3 nm.

A third luminescent layer was formed by depositing a mixture containing a mixture containing 92% by mass of CBP and 8% by mass of Ir(ppy)₃ so that a film thickness thereof became 10 nm.

Further, an electron transporting layer was formed by depositing BCP so that a film thickness thereof became 10 nm.

Chemical structure of the compound A (the above-exemplified compound (1)) is as follows. 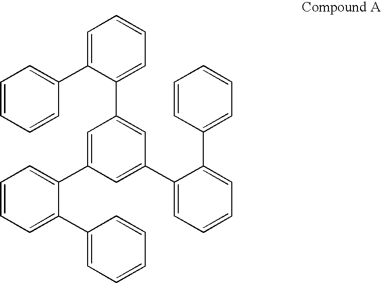
Evaluation

Using the electroluminescent devices obtained in Example 1 and Comparative example 1, the light-emitting efficiency, the light-emitting luminance and the chromaticity were evaluated according to the following method.

Using a source measure (trade name: UNIT TYPE 2400, manufactured by Toyo Corporation), a direct current voltage was applied to the electroluminescent device so as to have a light emission, and a light-emitting performance thereof was measured. The highest luminance at the time was defined to be Lₘₐₓ and the light-emitting efficiency at 1000 Cd/m² was defined to be the external quantum efficiency (η₁₀₀₀). Moreover, according to a light-emitting spectrum at the time, the CIE chromaticity coordinates were obtained. The obtained results are shown in the following Table 1.

Moreover, Eg and T1 of each of the organic compounds (compound A) included in the above-mentioned buffer layers and CBP were confirmed by the following method. The results are shown in the following Table 2.

Eg was obtained by the absorption end of the absorption spectrum of the deposition film of the compound alone.

T1 was obtained from the rise wavelength by cooling down the compound sample under a liquid nitrogen temperature and measuring the phosphorescence thereof.

TABLE 1

| | Highest | External quantum | CIE |
|---|---|---|---|
| | luminance | efficiency | chromaticity |
| | Lₘₐₓ(Cd/m²) | (η₁₀₀₀) | coordinate |
| Comparative example 1 | 36,000 | 4.00% | (0.31, 0.35) |
| Example 1 | 75,000 | 6.30% | (0.33, 0.34) |

TABLE 2

| | Eg (eV) | T1 (eV) |
|---|---|---|
| Compound A | 4.1 | 2.73 |
| CBP | 3.3 | 2.6 |

### Comparative Example 2

An electroluminescent device of Comparative example 2 was produced in the same manner as in Comparative example 1, except that the conformation of the organic compound layers are changed as follows.

A hole transporting layer was formed by depositing NPD so that a film thickness thereof become 40 nm.

A first luminescent layer was formed by depositing a mixture containing 92% by mass of CBP and 8% by mass of FIrpic so that a film thickness thereof became 10 nm.

A first buffer layer was formed by depositing BCP so that a film thickness thereof became 3 nm.

Further, a second luminescent layer was formed by depositing a mixture containing 92% by mass of CBP and 8% by mass of Btp₂Ir(acac) so that a film thickness thereof became 10 nm.

### Example 2

An electroluminescent device of Example 2 was produced in the same manner as in Comparative example 2, except that the conformation of the organic compound layers are changed as follows.

A hole transporting layer was formed by depositing NPD so that a film thickness thereof become 40 nm.

A first luminescent layer was formed by depositing a mixture containing 92% by mass of CBP and 8% by mass of Flrpic so that a film thickness thereof became 10 nm.

A first buffer layer was formed by depositing a mixture containing 75% by mass of the compound A and 25% by mass of BCP so that a film thickness thereof became 3 nm.

Further, a second luminescent layer was formed by depositing a mixture containing 92% by mass of CBP and 8% by mass of Btp₂Ir(acac) so that a film thickness thereof became 10 nm.

Evaluation

Evaluation was conducted using Example 2 and Comparative example 2 in the same manner as for Example 1. The obtained results are shown in the following Table 3. Moreover, Eg and T1 of each of the organic compounds (compound A) included in the above-mentioned buffer layers, CBP and BCP are shown in the following Table 4.

TABLE 3

| | Highest | External quantum | CIE |
|---|---|---|---|
| | luminance | efficiency | chromaticity |
| | Lₘₐₓ(Cd/m²) | (η₁₀₀₀) | coordinate |
| Comparative example 2 | 23,000 | 2.30% | (0.31, 0.39) |
| Example 2 | 65,000 | 5.70% | (0.33, 0.35) |

TABLE 4

| | Eg (eV) | T1 (eV) |
|---|---|---|
| Compound A | 4.1 | 2.73 |
| CBP | 3.3 | 2.6 |
| BCP | 3.6 | 2.52 |

### Comparative Example 3

A glass substrate having a 0.5 mm thickness and an ITO film of a 2.5 cm square size (manufactured by Geomatic Co., Ltd., surface resistance: 10 Ω/□) was placed in a washing container so as to have an ultrasonic wave washing with a 2-propanol, then a UV-ozone process was carried out for 30 minutes so as to provide an ITO substrate.

The following organic compound layers were deposited successively by the vacuum deposition method onto the ITO substrate.

A hole transporting layer was formed by depositing NPD so that a film thickness thereof became 40 nm.

A first luminescent layer was formed by depositing 1-[3,5-di(1-pyrenyl)-phenyl]-pyrene so that a film thickness thereof became 24 nm.

A second luminescent layer was formed by depositing a mixture containing 86% by mass of CBP and 14% by mass of Ir(ppy)₃ so that a film thickness thereof became 24 nm.

A third luminescent layer was formed by depositing a mixture containing a mixture containing 97% by mass of CBP and 3% by mass of iridium bis(2-phenylquinoline) acetylacetonate so that a film thickness thereof became 24 nm.

Further, an electron transporting layer was formed by depositing 2,2′,2′-(1,3,5-benzenetolyl)tris[3-(2-methylphenyl)-3H-imidazo[4,5-b]pyridine] so that a film thickness thereof became 24 nm.

Subsequently, with a patterned mask (mask for forming a 5 mm×5 mm light-emitting region) placed on the electron transporting layer, a mixture containing magnesium and silver (a molar ratio of Mg:Ag in the mixture is 10:1) was deposited so as to have a thickness of 0.25 μm, and silver was further deposited so as to have a thickness of 0.3 μm in order to provide a cathode. Aluminum lead wires are connected to the anode and the cathode thereof so as to form an electroluminescent device. It was placed in a glove box substituted with a nitrogen gas and sealed in a sealing container made of glass by sealing using an ultraviolet ray hardening type adhesive (trade name: XNR5493, manufactured by Nagase-CIBA Ltd.).

As mentioned above, an electroluminescent device of Comparative example 3 was produced.

### Example 3

An electroluminescent device of Example 3 was produced in the same manner as in Comparative example 3, except that the conformation of the organic compound layers are changed as follows.

A hole transporting layer was formed by depositing NPD so that a film thickness thereof become 40 nm.

A first luminescent layer was formed by depositing 1-[3,5-di(1-pyrenyl)-phenyl]-pyrene so that a film thickness thereof became 24 nm.

A first buffer layer was formed by depositing a mixture containing 20% by mass of the compound A and 80% by mass of CBP so that a film thickness thereof became 7 nm.

A second luminescent layer was formed by depositing a mixture containing 86% by mass of CBP and 14% by mass of Ir(ppy)₃ so that a film thickness thereof became 24 nm.

A second buffer layer was formed by depositing a mixture containing 20% by mass of the compound A and 80% by mass of CBP so that a film thickness thereof became 7 nm.

A third luminescent layer was formed by depositing a mixture containing a mixture containing 97% by mass of CBP and 3% by mass of iridium bis(2-phenylquinoline) acetylacetonate so that a film thickness thereof became 24 nm.

Further, an electron transporting layer was formed by depositing 2,2′,2′-(1,3,5-benzenetolyl)tris[3-(2-methylphenyl)-3H-imidazo[4,5-b]pyridine] so that a film thickness thereof became 24 nm.

Chemical structures of 1-[3,5-di(1-pyrenyl)-phenyl]-pyrene, iridium bis(2-phenylquinoline) acetylacetonate and 2,2′,2″-(1,3,5-benzenetolyl)tris[3-(2-methylphenyl)-3H-imidazo[4,5-b]pyridine] are as follows.

### 1-[3,5-di(1- pyrenyl)-phenyl]-pyrene Iridium bis(2-phenylquinoline)acetylacetonate

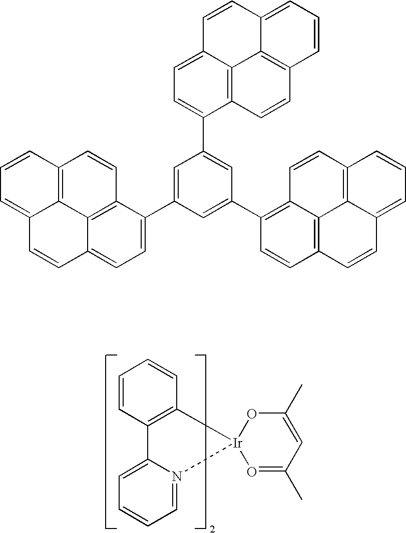

### 2,2′,2″-(1,3,5-benzenetolyl)tris[3-(2-methylphenyl)-3H-imidazo[4,5-b]pyridine]

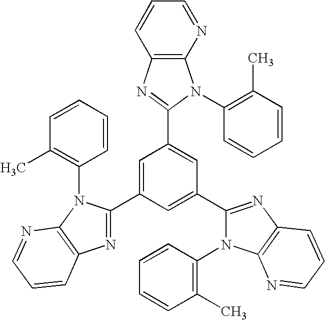 Evaluation

Evaluation was conducted using Example 3 and Comparative example 3 in the same manner as for Example 1. The obtained results are shown in the following Table 5.

TABLE 5

| | Highest | External quantum | CIE |
|---|---|---|---|
| | luminance | efficiency | chromaticity |
| | Lₘₐₓ(Cd/m²) | (η₁₀₀₀) | coordinate |
| Comparative example 3 | 78,000 | 7.50% | (0.29, 0.38) |
| Example 3 | 98,000 | 8.70% | (0.33, 0.35) |

Examples of the present invention, in which any one of the above-exemplified compounds (4), (11), (20), (35) and (44) is used in any one of Examples 1, 2 and 3 in place of the compound (A) (the above-exemplified compound (1)) also provide similar favorable results. Eg and TI of each of the above-exemplified compounds (4), (11), (20), (35) and (44) are shown in the following Table 6.

TABLE 6

| | Eg | |
|---|---|---|
| | (eV) | T1 (eV) |
| Exemplified compound (4) | 4.1 | 2.73 |
| Exemplified compound (11) | 4.2 | 2.78 |
| Exemplified compound (20) | 4.1 | 2.73 |
| Exemplified compound (35) | 4.0 | 2.73 |
| Exemplified compound (44) | 4.0 | 2.78 |

As is understood from the above results, the electroluminescent devices of the examples having a buffer layer, which containsg an organic compound having 4.0 eV or more Eg, between two or more different luminescent layers are extremely superior to the electroluminescent devices of the comparative examples having no buffer layer or having buffer layer containing no organic compound of the present invention in terms of every aspect of the light-emitting luminance, the light-emitting efficiency and the chromaticity.

The electroluminescent devices of the present invention can be preferably used in the fields of display devices, displays, backlights, electron photography, illumination light sources, recording light sources, exposing light sources, reading light sources, sigsn, billboards, interior, optical communication or the like.

What is claimed is:

1. An organic electroluminescent device comprising at least two luminescent layers provided between a pair of electrodes, wherein:
each of the luminescent layers contains a light-emitting material having a structure different from a structure of a light-emitting material contained in other luminescent layers;
at least one of the light-emitting materials is a phosphorescence light-emitting material;
each of the luminescent layers is adjacent to another luminescent layer via at least a buffer layer; and
the buffer layer includes an organic compound having an energy difference (Eg) between the highest occupied orbit and the lowest non-occupied orbit of 4.0 eV or more.

2. The organic electroluminescent device of claim 1, wherein the lowest excited triplet energy level (T1) of the organic compound is 2.7 eV or more.

3. The organic electroluminescent device of claim 1, wherein the buffer layer contains a hole transporting material or an electron transporting material.

4. The organic electroluminescent device of claim 1, wherein a film thickness of the buffer layer is in a range of 0.5 to 10 nm.

5. The organic electroluminescent device of claim 3, wherein a content of the hole transporting material or the electron transporting material in the buffer layer is in a range of 1 to 95% by mass relative to the a total mass of the buffer layer.

6. The organic electroluminescent device of claim 1, wherein the organic compound is a compound represented by the following Formula (1):
L-(Ar)ₘ Formula (1)
wherein Ar is a group represented by the following Formula (2); L is a benzene skeleton having a valence of 3 or more; and m is an integer of 3 or more; 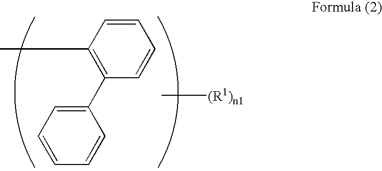
wherein R¹ is a substituent; in the case where R¹ is present in a plurality, they may either be the same or different from each other; and n1 is an integer from 0 to 9.

7. The organic electroluminescent device of claim 1, wherein the organic compound is a compound represented by the following Formula (3): 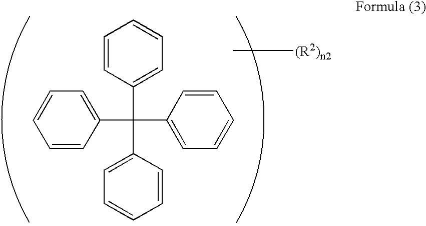
wherein R² is a substituent; in the case where R² is present in a plurality, they may either be the same or different from each other; and n2 is an integer from 0 to 20.

8. The organic electroluminescent device of claim 1, which is characterized by emitting white light.
